(19) United States
(12) Patent Application Publication
(10) Pub. No.: US 2026/0182263 A1
(43) Pub. Date: Jun. 25, 2026

(54) METHOD FOR MANUFACTURING HIGH-QUALITY GAN HEMT POWER SEMICONDUCTOR EPITAXIAL WAFER

(71) Applicant: WAVELORD CO., LTD., Gyeonggi-do (KR)

(72) Inventors: June O SONG, Gyeonggi-do (KR); Younghun HAN, Gyeonggi-do (KR); Hyun Chul LIM, Gyeonggi-do (KR); Yu Hyun BAK, Gyeonggi-do (KR)

(21) Appl. No.: 19/426,571

(22) Filed: Dec. 19, 2025

(30) Foreign Application Priority Data
Dec. 19, 2024 (KR) 10-2024-0191422
Dec. 19, 2025 (KR) 10-2025-0204554

(51) Int. Cl. H10P 14/20

(52) U.S. Cl. CPC H10P 14/3256; H10P 14/2905; H10P 14/3216; H10P 14/3251; H10P 14/3416

(57) ABSTRACT

A method for manufacturing a high-quality GaN HEMT power semiconductor epitaxial wafer according to the present disclosure includes forming a nucleation region on a growth substrate; and forming a 3-dimensional nitride structure region (3DNS region), a stress-relieving region, a buffer region, a channel region, and a barrier region on the nucleation region. The 3DNS region is formed at one or more positions among: between the nucleation region and the stress-relieving region, between individual regions within the stress-relieving region, between the stress-relieving region and the buffer region, between the buffer region and the channel region, and between the barrier region and a pGaN region formed thereon. The 3DNS region is formed of a nitride material having an energy bandgap smaller than that of a lower region.

### CROSS-REFERENCE TO RELATED APPLICATIONS

This application claims the benefit and priority to Korean Patent Application Nos. 10-2024-0191422, filed on December 19, 2024 and 10-2025-0204554, filed on December 19, 2025. The entire disclosures of the applications identified in this paragraph are incorporated herein by references.

### FIELD

The present disclosure relates to Group III nitride-based epitaxial growth and wafer manufacturing technology for power semiconductor devices. More specifically, it relates to a method for manufacturing a high-quality GaN HEMT power semiconductor epitaxial wafer capable of controlling crystal defects by introducing a 3-dimensional nitride structure (3DNS) between a growth substrate and a channel region, thereby improving device reliability while thinning the overall thickness.

### BACKGROUND

Recently, Gallium Nitride (GaN)-based High Electron Mobility Transistor (HEMT) epitaxial wafers have been widely used as core materials for power amplifiers in radio frequency (RF) communication modules, and converters and inverters for high-speed switching. Generally, such GaN HEMT devices are manufactured by stacking nitride layers on a Silicon (Si) or Silicon Carbide (SiC) growth substrate having excellent heat transfer characteristics.

However, when growing GaN on a silicon substrate, significant stress occurs during the film formation process due to the large difference in lattice constants (about 17%) and thermal expansion coefficients (about 56%) between the two materials, which causes a large amount of threading dislocations propagating in the growth direction. These crystal defects are transmitted to the upper channel region, causing a decrease in electron mobility of the device and an increase in leakage current.

Conventionally, in order to suppress vertical leakage current, a high-resistance layer was formed by artificially doping impurities such as carbon (C) or iron (Fe) into a GaN buffer layer. However, such a doping process has a side effect of further deteriorating crystal quality, and the buffer layer had to be grown to a thickness of several micrometers to ensure sufficient insulation performance. As the buffer layer becomes thicker, the path for heat generated during device operation to be released to the substrate becomes longer, increasing thermal resistance, which leads directly to shortened device life and reduced reliability.

In addition, the AlN nucleation layer used to prevent melt-back etching caused by the reaction between silicon and gallium is difficult to completely block the upward propagating dislocations by itself. Therefore, there is an urgent need for a new level of dislocation control technology capable of maximizing heat dissipation characteristics by ultra-thinning the device structure without degrading crystal quality.

### SUMMARY

### Technical Problem

An object of the present disclosure is to effectively block the upward propagation of crystal defects generated from a growth substrate to form a high-quality epitaxial layer.

Another object is to provide a method for manufacturing a high-reliability GaN HEMT power semiconductor wafer capable of stable operation even in high-temperature and high-pressure environments by significantly reducing the total thickness of the device to increase heat dissipation efficiency.

### Solution to Problem

To solve the above problems, a method for manufacturing a high-quality GaN HEMT power semiconductor epitaxial wafer according to an embodiment of the present disclosure includes: forming a nucleation region on a growth substrate; and forming a 3-dimensional nitride structure region (3DNS region), a stress-relieving region, a buffer region, a channel region, and a barrier region on the nucleation region, wherein the 3DNS region is formed at one or more positions among: between the nucleation region and the stress-relieving region, between individual regions within the stress-relieving region, between the stress-relieving region and the buffer region, between the buffer region and the channel region, and between the barrier region and a pGaN region formed thereon, and wherein the 3DNS region is formed of a nitride material having an energy bandgap smaller than that of a lower region.

In the method for manufacturing a high-quality GaN HEMT power semiconductor epitaxial wafer according to an embodiment of the present disclosure, the 3DNS region is formed of at least one material selected from the group consisting of GaN, AlGaN, InN, AlN, AlInN, InGaN, AlGaInN, MgN, and SiN.

In the method according to an embodiment of the present disclosure, the thickness of the 3DNS region is 2 nm to 10 nm.

In the method according to an embodiment of the present disclosure, the 3DNS region formed between the nucleation region and the stress-relieving region is formed of GaN, InGaN, or AlGaN having a lower Al composition than the stress-relieving region, thereby blocking the propagation of crystal defects.

In the method according to an embodiment of the present disclosure, the 3DNS region formed between the stress-relieving region and the buffer region is formed of GaN, MgN, or SiN, thereby reorganizing crystallinity before growing the buffer region and blocking vertical leakage current.

In the method according to an embodiment of the present disclosure, the 3DNS region formed between the buffer region and the channel region is formed of InGaN or AlGaInN, thereby blocking dopant diffusion from the buffer region.

In the method according to an embodiment of the present disclosure, the stress-relieving region is characterized in that a plurality of AlGaN regions are stacked or an Al(Ga)N/AlGaN superlattice structure is included.

In the method according to an embodiment of the present disclosure, prior to forming the channel region, the method further includes forming a back-barrier region of AlGaN or a 2H-Al(Ga)N/4H-SiC(N) superlattice structure.

In the method according to an embodiment of the present disclosure, the forming of the 3DNS region includes: a step of preflowing a Group III element source without supplying a nitrogen (N) source to form nano-scale precursor clusters; and a step of supplying a nitrogen source to the precursor clusters to form a 3DNS region in which the precursor clusters are recrystallized into a single crystal.

In the method according to an embodiment of the present disclosure, the 3DNS region has a composition ratio varying along a lateral direction, and a variation period of the composition ratio is 100 nm or less.

### Advantageous Effects of Invention

According to the present disclosure, the 3DNS region effectively bends or annihilates threading dislocations generated from the bottom, implementing the upper channel region in a substantially 'Threading dislocation free' state, thereby dramatically improving the electrical characteristics of the device.

In addition, interface stress caused by the difference in lattice constant and thermal expansion coefficient between the nucleation region and the channel region is controlled to suppress wafer warpage or crack generation.

Furthermore, thanks to the improvement in crystal quality, the conventional thick high-resistance doping buffer layer can be minimized or eliminated, and accordingly, the total epitaxial structure can be ultra-thinned to 700 nm or less. Also, by thinning the device structure, heat generated during device operation is directly transferred to the substrate, maximizing heat dissipation capability and improving the life and reliability of the device.

In addition, it is possible to secure both the yield and quality of the manufacturing process by promoting the growth of a high-quality active region while preventing the melt-back etching phenomenon.

### BRIEF DESCRIPTION OF DRAWINGS

FIG. 1 is a structural diagram of an epitaxial wafer stack according to a first embodiment of the present disclosure.

FIGS. 2, 3, 4, and 5 are modified examples of FIG. 1.

FIG. 6 is a TEM photograph showing a state in which propagation of threading dislocations is blocked when the 3DNS region is introduced.

FIG. 7 is an enlarged TEM photograph showing an interface where a nano-scale 3DNS region is formed.

### DETAILED DESCRIPTION

Hereinafter, embodiments implementing a high-quality GaN HEMT power semiconductor epitaxial wafer and a manufacturing method thereof through the introduction of a 3-dimensional nitride structure according to the present disclosure will be described in detail with reference to the drawings.

The core of the present disclosure is to introduce a 3DNS region 190, which is a nano-scale three-dimensional structure, at a strategic location inside the epitaxial layer in order to simultaneously secure the crystal quality and heat dissipation characteristics of the power semiconductor.

The overall process flow of the present disclosure includes preparing a growth substrate and sequentially stacking an AlN nucleation region 120, a stress-relieving region 130, a buffer region 140, a channel region 160, and a barrier region 170 thereon, and includes a 3DNS region 190 formed through a special two-step growth method. The 3DNS region 190 acts as a physical barrier that fundamentally blocks vertical propagation of dislocations by intentionally aggregating precursor clusters at defect tips of a lower layer, and as a functional interface that relieves interlayer stress.

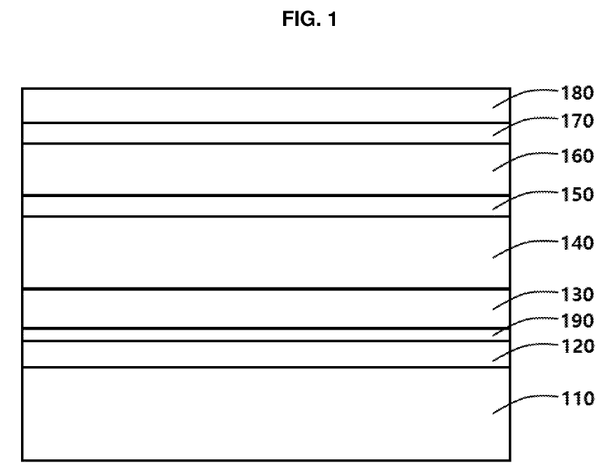

Referring to FIG. 1, the epitaxial wafer according to the present embodiment includes an AlN nucleation region 120, a stress-relieving region 130, a buffer region 140, a channel region 160, and a barrier region 170 sequentially stacked on a growth substrate 110.

The growth substrate 110 is a base for epitaxial growth, and a silicon (Si) substrate is used. In particular, the crystal plane direction of the silicon substrate 110 is preferably the (111) plane, due to the atomic arrangement similarity with the hexagonal nitride semiconductor. In addition, a high-resistance or p-type silicon substrate is used to suppress vertical leakage current through the substrate. Alternatively, a growth substrate 110 made of silicon carbide (SiC) may also be applied.

A nucleation region 120 is formed on the growth substrate 110. It is mainly composed of aluminum nitride (AlN) and serves as a diffusion barrier to improve wetting between the silicon substrate and the upper nitride layer and prevent melt-back phenomenon in which the substrate is etched during high-temperature growth.

A stress-relieving region 130 is formed on the nucleation region 120. This is a layer for controlling tensile stress caused by a difference in thermal expansion coefficients between silicon and GaN, and may include a stack of a plurality of AlGaN regions or an Al(Ga)N/AlGaN superlattice structure.

A buffer region 140 is formed on the stress-relieving region 130. The buffer region 140 is a layer that secures high resistance to implement breakdown voltage characteristics, and reinforces insulation characteristics by intentionally doping impurities such as carbon (C) or iron (Fe) into GaN.

A back-barrier region 150 may be provided under the channel region 160. In particular, as a modified example of the present disclosure, the back-barrier region 150 may have a superlattice structure in which 2H-Al(Ga)N material layers and 4H-SiC(N) material layers are alternately stacked, which maximizes the electron confinement effect while suppressing dislocation generation using lattice matching.

The channel region 160 is made of high-purity GaN and serves as an electron movement path, and the barrier region 170 thereon is made of AlGaN or the like to form a high-concentration two-dimensional electron gas (2DEG) through interface polarization. A pGaN layer 180 may be formed on the uppermost layer to make the device normally-off.

In this embodiment, the 3DNS region 190 is introduced above the nucleation region 120 as a region where the composition ratio varies along the lateral direction. Discontinuous and non-uniform nano-scale dot-shaped structures 191 are formed in the 3DNS region 190 to filter threading dislocations propagating from the bottom. This has technical significance in innovatively improving the crystal quality of the upper channel region by preferentially forming at defect points of the lower layer to block or bend the propagation path of dislocations.

The 3DNS region 190 is formed of a nitride material having a smaller energy bandgap than the nitride layer located in the nucleation region 120, which is the lower part of the corresponding region. The 3DNS region 190 is selected from GaN, AlGaN, InN, AlN, AlInN, InGaN, AlGaInN, MgN, and SiN. Specifically, in this embodiment, the 3DNS region 190 may be an AlxInyGa1-x-yN composition, and has a structural feature in which the composition ratios of x and y vary along the lateral direction. When the lower layer is AlN or AlGaN, the 3DNS is formed of a GaN or InGaN-based material to form an energy step. This physical coupling relationship of the energy bandgap provides a driving force for inhibiting the growth of dislocation lines and inducing annihilation, enabling the growth of a high-quality active layer.

Here, the stress dispersion effect can be further enhanced by nitriding the surface of the nucleation region before forming the 3DNS region, or by modifying the 3DNS itself with a material having a large lattice constant such as AlInN. At this time, the 3DNS region 190 has a composition ratio change period of 100 nm or less in the lateral direction, which induces high-density local stress modulation so that threading dislocations cannot propagate in a straight line and are annihilated. Thanks to this high-density defect control effect, the thickness of the buffer region 140 can be reduced, enabling further improvement in heat dissipation performance.

The thickness of the 3DNS region 190 according to the present disclosure is formed in a range of 2 nm or more and 10 nm or less, and preferably secures a thickness of 3 nm or more to maximize the dislocation blocking function. Physically, if it is less than 2 nm, the dislocation blocking ability is reduced due to lack of structural continuity, and if it exceeds 10 nm, the total epitaxial thickness increases, increasing vertical thermal resistance. Therefore, by maintaining the thickness at 10 nm or less, defects are effectively blocked while the heat transfer path is shortened to improve heat dissipation capability.

In the 3DNS region 190, each nano-scale dot-shaped structure 191 acts as an independent filter, and by blocking threading dislocations propagating upward from the growth substrate, it fundamentally solves the reliability degradation problem that may occur in the final device. Meanwhile, the present disclosure ultra-thins the entire epitaxial structure to 700 nm or less, preferably 500 nm or less, based on securing crystal quality through 3DNS.

Specifically, the buffer region 140 maintains a high resistance state by doping with carbon (C) or iron (Fe) to secure the breakdown voltage of the device. In the present disclosure, the dislocation density is drastically lowered by introducing the 3DNS region 190 before, after, or inside the buffer region formation step. As a result, the problem of crystallinity degradation due to doping can be offset, and sufficient leakage current blocking characteristics can be secured with only a buffer region much thinner than the conventional one, enabling thinning of the entire epitaxy and high heat dissipation capability.

Next, a process of forming the 3DNS region 190 will be described. The process of forming a 3-dimensional shaped structure undergoes a step of preflowing only a Group III element source without a nitrogen (N) source to form nano-scale precursor clusters, and then supplying a nitrogen source to recrystallize into a single crystal. After forming the nucleation region 120 on the growth substrate 110, only Group III element (Al, Ga, In) sources are preflowed without ammonia (NH3) gas to form precursor clusters 131a. Thereafter, ammonia gas is supplied to recrystallize the clusters into a single crystal, thereby completing the final 3DNS region 190.

In the present disclosure, the formation of the 3DNS region 190 utilizes a pyrolysis reaction of an organometallic source. Thermodynamically, Group III elements preferentially aggregate at unstable surface points with high energy, that is, around the surface where threading dislocations exist, forming clusters of a 3-dimensional dot shape 191. This has a technical effect of physically blocking the growth path of dislocations or changing their characteristics, and fundamentally suppresses the propagation of dislocations to the top through a subsequent recrystallization process.

In the present disclosure, the formation of the 3DNS region 190 may be repeated two or more times. By repeating the process, the thickness of the 3DNS region can be increased and the composition change period in the lateral direction can be precisely controlled, thereby further strengthening dislocation filtering and stress relaxation functions. This repetitive process allows arbitrary adjustment according to the design conditions of the channel and barrier regions to be grown thereon, ensuring optimal crystallinity.

Meanwhile, in the present disclosure, process parameters for each step are precisely controlled to induce 3-dimensional growth. The 3DNS region 190 is formed under a temperature of 600 to 1300°C and a pressure of 30 to 400 torr, and the V/III ratio is maintained in the range of 300 to 4000. The growth atmosphere gas uses a N₂/H₂ mixed gas to optimize the crystallinity of the recrystallized 3DNS, which becomes the basis for securing high electron mobility in a 100% H₂ atmosphere during subsequent channel region growth.

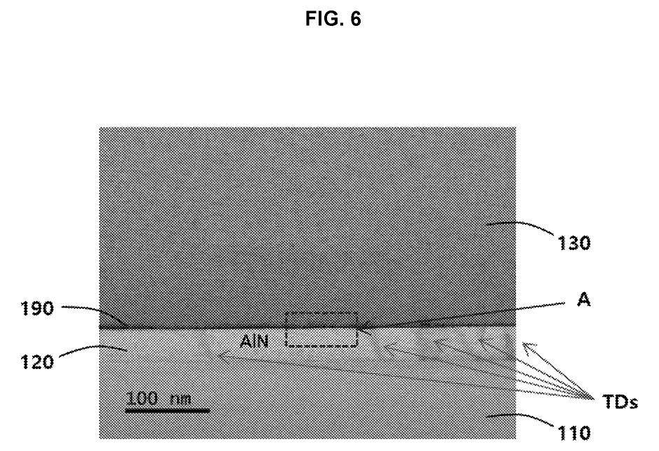

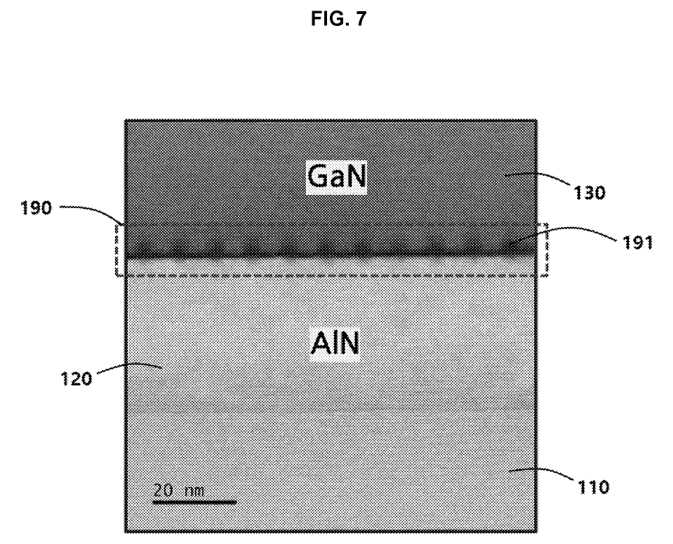

The TEM photographs of FIGS. 6 and 7 visually demonstrate the effect of 3DNS according to the present disclosure. Referring to the TEM photograph of FIG. 6, it can be seen that the 3DNS region inserted on the AlN nucleation region effectively blocks the lower threading dislocation. As a result, the upper region maintains a high-purity crystal state (Threading dislocation free) with almost no defects. FIG. 7 is a further enlarged photograph of the interface, clearly showing the nano-scale 3DNS layer formed between the AlN layer and the upper layer. This 3DNS region maintains an optimal thickness of 2 nm to 10 nm and has a structure in which the composition ratio changes in the lateral direction, maximizing the crystal quality of the upper active layer.

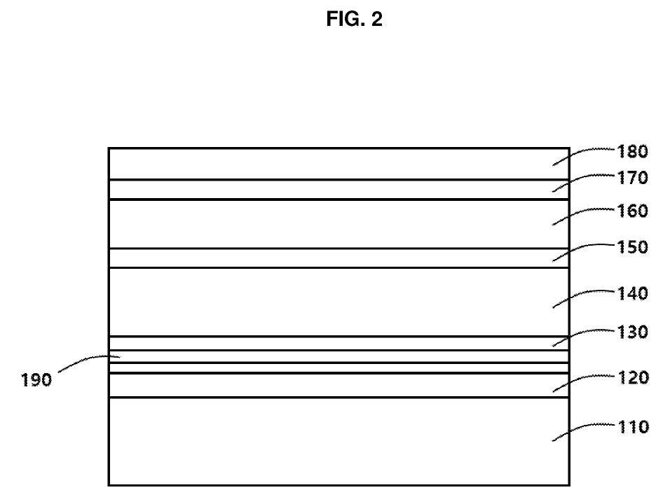

FIG. 2 shows a structure in which a 3DNS region is inserted between individual regions within the stress-relieving region 130. In this embodiment, the 3DNS region 190 is preferably composed of GaN or AlGaN having a lower Al content than the lower layer between AlGaN regions having different Al compositions. This relieves sudden changes in the interlayer lattice constant to resolve thermo-mechanical stress and suppress crack generation. Here, the stress relaxation effect can be maximized by arranging 3DNS at each step interface of a step-graded structure in which the Al composition gradually decreases toward the top.

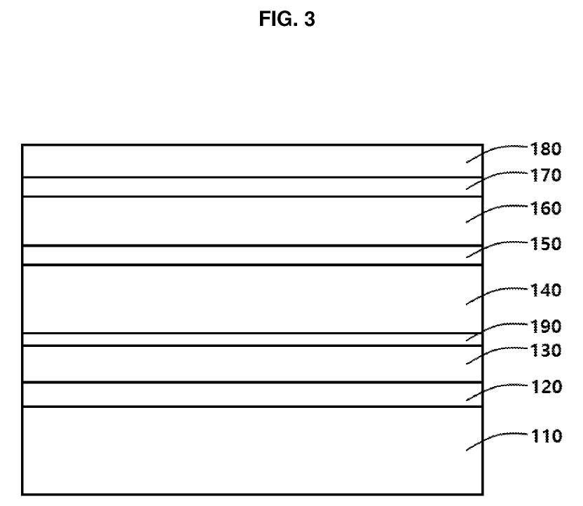

FIG. 3 shows a structure in which a 3DNS region is formed between the stress-relieving region 130 and the buffer region 140. In this embodiment, the 3DNS region 190 is preferably composed of GaN, MgN, or SiN. This reorganizes crystallinity immediately before the buffer region where high-resistance doping begins, and reinforces the energy barrier through MgN or SiN, thereby maximizing vertical leakage current blocking performance during high voltage driving. Here, in order to strengthen leakage current blocking performance, a composite 3DNS structure combining a very thin AlN layer with the MgN or SiN 3DNS region may be applied, or insulating properties may be strengthened by locally preflowing an insulating dopant such as Fe at a high concentration during 3DNS formation.

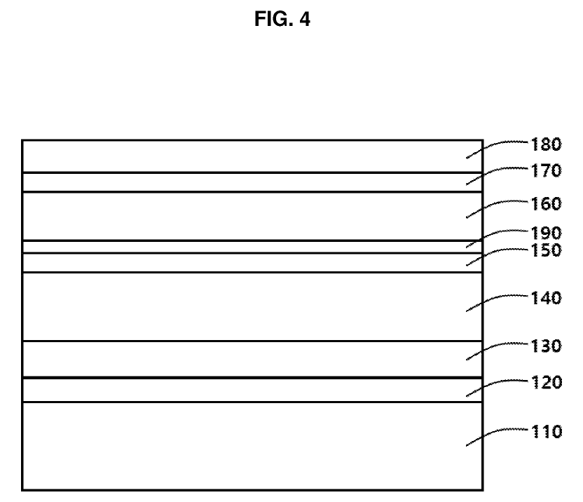

FIG. 4 is an embodiment in which a 3DNS region is inserted between the buffer region 140 and the channel region 160. In this embodiment, the 3DNS region 190 is preferably composed of InGaN or AlGaInN. Thereby, it acts as a diffusion barrier that physically blocks impurities such as carbon (C) or iron (Fe) doped in the lower buffer region from diffusing into the active channel. Through this, the quality of the channel interface is improved to dramatically improve the electron mobility characteristics of the 2DEG. Here, the electrical purity of the lower part of the channel can be maximized by oscillating the In composition of the InGaN 3DNS region in the horizontal direction, or by alternately stacking a 2H-Al(Ga)N/4H-SiC(N) superlattice structure and 3DNS.

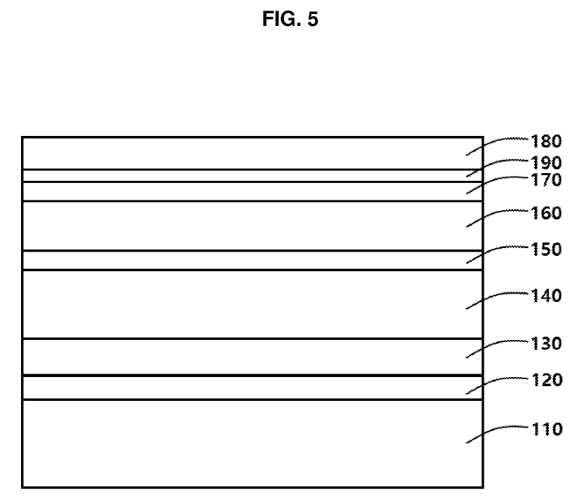

FIG. 5 shows a structure in which a 3DNS region is arranged between the barrier region 170 and the pGaN region 180. In this embodiment, it is preferable that a nitride having a high GaN or InN content is used for the 3DNS region 190. Thereby, a physical environment for reducing crystal defects of the upper pGaN and increasing hole concentration is provided. In addition, it is significant in securing thermal stability of the device and optimizing heat dissipation performance by rapidly dispersing heat generated from the lower part of the gate horizontally.

What is claimed is:

1. A method for manufacturing a high-quality GaN HEMT power semiconductor epitaxial wafer, the method comprising:
forming a nucleation region on a growth substrate; and
forming a 3-dimensional nitride structure region (3DNS region), a stress-relieving region, a buffer region, a channel region, and a barrier region on the nucleation region,
wherein the 3DNS region is formed at one or more positions selected from the group consisting of: between the nucleation region and the stress-relieving region, between individual regions within the stress-relieving region, between the stress-relieving region and the buffer region, between the buffer region and the channel region, and between the barrier region and a pGaN region formed thereon, and
wherein the 3DNS region is formed of a nitride material having an energy bandgap smaller than an energy bandgap of a lower region.

2. The method of claim 1, wherein the 3DNS region is formed of at least one material selected from the group consisting of GaN, AlGaN, InN, AlN, AlInN, InGaN, AlGaInN, MgN, and SiN.

3. The method of claim 1, wherein a thickness of the 3DNS region is 2 nm to 10 nm.

4. The method of claim 1, wherein the 3DNS region formed between the nucleation region and the stress-relieving region is formed of GaN, InGaN, or AlGaN having a lower Al composition than the stress-relieving region, to block propagation of crystal defects.

5. The method of claim 1, wherein the 3DNS region formed between the stress-relieving region and the buffer region is formed of GaN, MgN, or SiN, to reorganize crystallinity prior to growth of the buffer region and block vertical leakage current.

6. The method of claim 1, wherein the 3DNS region formed between the buffer region and the channel region is formed of InGaN or AlGaInN, to block dopant diffusion from the buffer region.

7. The method of claim 1, wherein the stress-relieving region comprises a stack of a plurality of AlGaN regions or comprises an Al(Ga)N/AlGaN superlattice structure.

8. The method of claim 1, further comprising, prior to forming the channel region, forming a back-barrier region of AlGaN or a 2H-Al(Ga)N/4H-SiC(N) superlattice structure.

9. The method of claim 1, wherein the forming of the 3DNS region comprises:
preflowing a Group III element source without supplying a nitrogen (N) source to form nano-scale precursor clusters; and
supplying a nitrogen source to the precursor clusters to form the 3DNS region in which the precursor clusters are recrystallized into a single crystal.

10. The method of claim 9, wherein the 3DNS region has a composition ratio varying along a lateral direction, and a variation period of the composition ratio is 100 nm or less.
